(19) United States
(12) Patent Application Publication
(10) Pub. No.: US 2026/0290470 A1
(43) Pub. Date: Sep. 24, 2026

(54) SEMICONDUCTOR MEMORY DEVICE

(71) Applicant: Kioxia Corporation, Tokyo (JP)

(72) Inventors: Yoshinao SUZUKI, Yokohama Kanagawa (JP); Takatoshi MINAMOTO, Kamakura Kanagawa (JP)

(73) Assignee: Kioxia Corporation, Tokyo (JP)

(21) Appl. No.: 19/322,746

(22) Filed: Sep. 9, 2025

(30) Foreign Application Priority Data
Mar. 24, 2025 (JP) 2025-048726

(51) Int. Cl. G11C 16/30; G11C 5/14; G11C 11/4074; G11C 11/4076; G11C 16/04; G11C 16/32; H10B 43/10; H10B 43/27; H10B 43/35

(52) U.S. Cl. CPC G11C 16/30; G11C 5/145; G11C 5/147; G11C 11/4074; G11C 11/4076; G11C 16/0466; G11C 16/32; H10B 43/10; H10B 43/27; H10B 43/35

(57) ABSTRACT

In general, according to one embodiment, a semiconductor memory device includes: a memory cell; and first and second power supply domains coupled to first and second power supply pads to which first and second voltages are input, respectively, the first power supply domain including a sequencer and the second power supply domain including a charge pump circuit that generates a voltage to be applied to the memory cell, wherein the charge pump circuit includes a first diode having an input terminal coupled to an input terminal of the charge pump circuit, a second diode having an output terminal coupled to an output terminal of the charge pump circuit, and first and second capacitors each having a first end coupled to an output terminal of the first and the second diode respectively and a second end coupled to the second power supply pad.

### CROSS-REFERENCE TO RELATED APPLICATION

This application is based upon and claims the benefit of priority from Japanese Patent Application No. 2025-048726, filed Mar. 24, 2025, the entire contents of which are incorporated herein by reference.

### FIELD

Embodiments described herein relate generally to a semiconductor memory device.

### BACKGROUND

As semiconductor memory devices, a NAND flash memory which is a nonvolatile semiconductor memory device and a DRAM which is a volatile semiconductor memory device are known.

### BRIEF DESCRIPTION OF DRAWINGS

FIG. 1 is a block diagram illustrating an example of a configuration of an information processing system according to a first embodiment.

FIG. 2 is a block diagram illustrating an example of a configuration of a semiconductor memory device according to the first embodiment.

FIG. 3 is a block diagram illustrating an example of a power supply configuration in the semiconductor memory device according to the first embodiment.

FIG. 4 is a circuit diagram illustrating an example of a circuit configuration of a memory cell array according to the first embodiment.

FIG. 5 is a cross-sectional view illustrating an example of a structure of the memory cell array according to the first embodiment.

FIG. 6 is a cross-sectional view taken along line VI-VI in FIG. 5, illustrating an example of a cross-sectional structure of a memory pillar in the memory cell array according to the first embodiment.

FIG. 7 is a block diagram illustrating an example of a configuration of a voltage generator according to the first embodiment.

FIG. 8 is a circuit diagram illustrating an example of a circuit configuration of the voltage generator according to the first embodiment.

FIG. 9 is a block diagram illustrating an example of changing the number of stages of charge pump units in a charge pump circuit included in the voltage generator according to the first embodiment.

FIG. 10 is a graph illustrating a relationship between an output voltage and an output current in the voltage generator included in the semiconductor memory device according to the first embodiment.

FIG. 11 is a graph illustrating a relationship between the output voltage and power efficiency in the voltage generator included in the semiconductor memory device according to the first embodiment.

FIG. 12 is a block diagram illustrating an example of a power supply configuration in a semiconductor memory device according to a second embodiment.

FIG. 13 is a block diagram illustrating an example of a configuration of the semiconductor memory device according to the second embodiment.

FIG. 14 is a circuit diagram illustrating an example of a circuit configuration of a voltage generator according to the second embodiment.

FIG. 15 is a circuit diagram illustrating an example of a circuit configuration of a voltage generator according to a third embodiment.

FIG. 16 is a command sequence diagram illustrating an example of setting of voltage value information in a memory system according to the third embodiment.

FIG. 17 is a circuit diagram illustrating components of a memory cell included in a memory cell array and coupling of the components in a semiconductor memory device according to a fourth embodiment.

### DETAILED DESCRIPTION

In general, according to one embodiment, a semiconductor memory device includes: a memory cell; a first power supply domain coupled to a first power supply pad to which a first voltage is input, the first power supply domain including a sequencer; and a second power supply domain coupled to a second power supply pad to which a second voltage is input, the second power supply domain including a charge pump circuit that generates a voltage to be applied to the memory cell, wherein the charge pump circuit includes a first diode having an input terminal coupled to an input terminal of the charge pump circuit, a first capacitor having a first end coupled to an output terminal of the first diode and a second end coupled to the second power supply pad, a second diode having an output terminal coupled to an output terminal of the charge pump circuit, and a second capacitor having a first end coupled to an output terminal of the second diode and a second end coupled to the second power supply pad.

Hereinafter, embodiments will be described with reference to the drawings. The drawings are schematic, and dimensions and ratios in the drawings are not necessarily the same as actual dimensions and ratios. In the following description, components having the same functions and configurations are denoted by the same reference signs. In a case where elements having similar configurations are particularly distinguished from each other, different characters or numbers may be added to the end of the same reference sign.

In the following description, a case where a first element is “coupled” to another second element includes a case where the first element is coupled to the second element either indirectly via an intermediate element that is always or selectively conductive, or directly without an intermediate element.

Hereinafter, as an example of the semiconductor memory device according to the embodiment, in each of first to third embodiments, a NAND flash memory that is a nonvolatile semiconductor memory device will be described. In a fourth embodiment, a dynamic random access memory (DRAM) that is a volatile semiconductor memory device will be described.

### 1. First Embodiment

### 1.1 Configuration

### 1.1.1 Information Processing System

An information processing system according to the first embodiment will be described. FIG. 1 is a block diagram illustrating an example of a configuration of the information processing system according to the first embodiment. As illustrated in FIG. 1, the information processing system 1 includes a host 2 and a memory system 3.

The host 2 is a data processing apparatus that processes data using the memory system 3. The host 2 is, for example, an electronic device such as a personal computer or a mobile terminal.

The memory system 3 is a storage apparatus configured to be coupled to the host 2. The memory system 3 is, for example, a memory card such as an SD™ card, a universal flash storage (UFS), or a solid state drive (SSD). The memory system 3 performs a data write operation, a data read operation, and a data erase operation in response to a request from the host 2.

### 1.1.2 Memory System

Subsequently, an internal configuration of the memory system 3 according to the first embodiment will be described with reference to FIG. 1.

The memory system 3 includes a semiconductor memory device 10 and a memory controller 20. The semiconductor memory device 10 and the memory controller 20 may constitute one semiconductor memory device by, for example, a combination thereof.

The semiconductor memory device 10 is, for example, a NAND flash memory capable of storing data in a nonvolatile manner. The semiconductor memory device 10 can also be referred to as a memory device.

The memory controller 20 includes, for example, an integrated circuit such as a system on a chip (SoC). A function of each unit of the memory controller 20 can be implemented by dedicated hardware, a program, and a processor that executes firmware, or a combination thereof. The memory controller 20 controls the semiconductor memory device 10 based on a request from the host 2. Specifically, the memory controller 20 writes data requested to be written to the semiconductor memory device 10 based on a write command from the host 2. In addition, the memory controller 20 reads data requested to be read from the semiconductor memory device 10 based on a read command from the host 2 and outputs the data to the host 2.

### 1.1.3 Memory Controller

Subsequently, an internal configuration of the memory controller 20 according to the first embodiment will be described with reference to FIG. 1.

The memory controller 20 includes a control circuit 21, a buffer memory 22, a host interface circuit (host I/F) 23, a memory interface circuit (memory I/F) 24, and an error checking and correcting (ECC) circuit 25, which are coupled to each other via an internal bus. Functions of the memory controller 20 described below can be implemented by either a hardware configuration or a configuration using a combination of a hardware resource and firmware.

The control circuit 21 controls the entire operation of the memory controller 20. The control circuit 21 includes, for example, a processor such as a central processing unit (CPU) and a volatile storage apparatus such as a static random access memory (SRAM) or a dynamic random access memory (DRAM) that is used as a work area of the processor. For example, the control circuit 21 orders the semiconductor memory device 10 to perform a write operation, a read operation, and an erase operation based on a request from the host 2.

The buffer memory 22 is, for example, a volatile storage apparatus such as an SRAM or a DRAM. The buffer memory 22 temporarily stores write data received from the host 2 and read data received by the memory controller 20 from the semiconductor memory device 10. The buffer memory 22 may be disposed outside the memory controller 20.

The host interface circuit 23 is coupled to the host 2 via a host bus. The host bus conforms to, for example, Peripheral Component Interconnect EXPRESS (PCI EXPRESS™ (PCIe)), SD™ interface, Small Computer System Interface (Serial Attached SCSI (SAS)), Serial ATA (Advanced Technology Attachment (SATA)), or Non-Volatile Memory EXPRESS (NVM EXPRESS™ (NVMe)). The host interface circuit 23 manages communication between the host 2 and the memory controller 20. For example, the host interface circuit 23 transfers a command and data received from the host 2 to the control circuit 21 and the buffer memory 22, respectively.

The memory interface circuit 24 is coupled to the semiconductor memory device 10 via a memory bus BUS. The memory bus BUS conforms to, for example, a single data rate (SDR) interface, a toggle double data rate (DDR) interface, or an open NAND flash interface (ONFI). The memory interface circuit 24 manages communication between the memory controller 20 and the semiconductor memory device 10. The memory interface circuit 24 transmits a command, address information, and write data to the semiconductor memory device 10 in accordance with an instruction of the control circuit 21. In addition, the memory interface circuit 24 receives read data from the semiconductor memory device 10.

The error checking and correcting circuit 25 performs error detection and correction processing on data stored in the semiconductor memory device 10. More specifically, at the time of writing of data, the error checking and correcting circuit 25 generates a parity of an error correction code and gives the parity to the write data. The error correction code is, for example, a hard bit decoding code such as a Bose-Chaudhuri-Hocquenghem (BCH) code or a Reed-Solomon (RS) code, or a soft bit decoding code such as a low-density parity-check (LDPC) code. In addition, the error checking and correcting circuit 25 performs processing of decoding the error correction code and detects whether an error is present during a data read operation. When an error is detected, a bit position where the error is detected can be identified and the error can be corrected. In the error checking and correcting circuit 25, the number of error correctable bits, which is an upper limit of the number of errors correctable, is set.

### 1.1.4 Semiconductor Memory Device

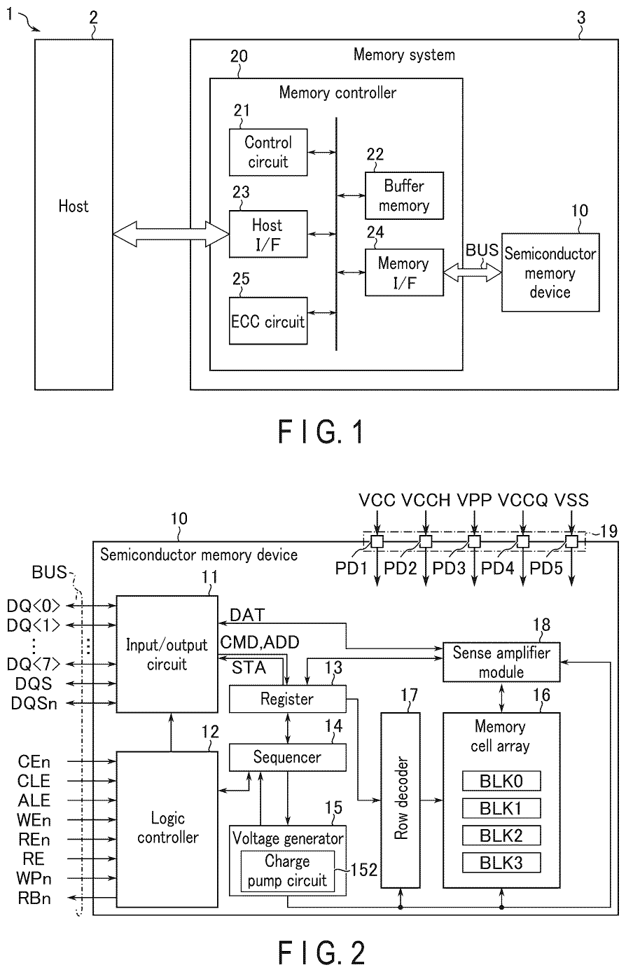

Next, an internal configuration of the semiconductor memory device according to the first embodiment will be described. FIG. 2 is a block diagram illustrating an example of a configuration of the semiconductor memory device according to the first embodiment.

The semiconductor memory device 10 includes an input/output circuit 11, a logic controller 12, a register 13, a sequencer 14, a voltage generator 15, a memory cell array 16, a row decoder 17, a sense amplifier module 18, and a power supply pad group 19.

The input/output circuit 11 and the logic controller 12 are interface circuits that transmit and receive various signals to and from the memory controller 20 via the memory bus BUS. Signals transmitted and received by the input/output circuit 11 include, for example, signals DQ<0>, DQ<1>, . . . , and DQ<7> (the signals are collectively referred to as a signal DQ<7:0>), DQS, and DQSn. Signals transmitted and received by the logic controller 12 include, for example, signals CEn, CLE, ALE, WEn, RE, REn, WPn, and RBn. In the present specification, n at the end of the name of each of the signals indicates logic obtained by inverting logic of a signal having the name without n. Specifically, a signal having a name without n at the end means that the signal is asserted when the signal is at an “H (High)” level. A signal having a name with n at the end means that the signal is asserted when the signal is at an “L (Low)” level.

The signal DQ<7:0> is, for example, a signal having an 8-bit width. The signal DQ<7:0> is actual data transmitted and received by the semiconductor memory device 10 and the memory controller 20. The signal DQ<7:0> includes, for example, data DAT, a command CMD, address information ADD, and status information STA. The data DAT includes read data and write data.

The signals DQS and DQSn are data strobe signals. The signals DQS and DQSn notify the semiconductor memory device 10 and the memory controller 20 of the timing of inputting and outputting the signal DQ<7:0>.

The signal CEn is a chip enable signal. The signal CEn enables the semiconductor memory device 10.

The signals CLE and ALE are a command latch enable signal and an address latch enable signal, respectively. The signals CLE and ALE notify the semiconductor memory device 10 that the signal DQ<7:0> input from the memory controller 20 includes the command CMD and the address information ADD.

The signal WEn is a write enable signal. The signal WEn instructs the semiconductor memory device 10 to write the input signal DQ<7:0>.

The signals RE and REn are read enable signals. The signals RE and REn instruct the semiconductor memory device 10 to output the signal DQ<7:0>.

The signal WPn is a write protect signal. The signal WPn instructs the semiconductor memory device 10 to prohibit the write operation and the erase operation.

The signal RBn is a ready busy signal. The signal RBn indicates whether the semiconductor memory device 10 is in a ready state (a state in which the semiconductor memory device 10 receives a command from the memory controller 20) or a busy state (a state in which the semiconductor memory device 10 does not receive a command from the memory controller 20).

The input/output circuit 11 transmits the address information ADD and the command CMD in the signal DQ<7:0> input from the memory controller 20 to the register 13, and transmits the write data DAT in the signal DQ<7:0> input from the memory controller 20 to the sense amplifier module 18. The input/output circuit 11 outputs the status information STA and the read data DAT received from the register 13 and the sense amplifier module 18, respectively, to the memory controller 20.

The logic controller 12 receives various control signals input from the memory controller 20. The logic controller 12 controls each of the input/output circuit 11 and the sequencer 14 based on the control signals. For example, the logic controller 12 notifies the input/output circuit 11 that the signal DQ<7:0> received by the input/output circuit 11 is the command CMD, the address information ADD, or the like. The logic controller 12 orders the input/output circuit 11 to input or output the signal DQ<7:0>. The logic controller 12 controls the sequencer 14 to enable the semiconductor memory device 10. In addition, the logic controller 12 outputs the signal RBn to the memory controller 20 to notify whether the semiconductor memory device 10 is in the ready state or the busy state.

The register 13 temporarily stores the command CMD, the address information ADD, and the status information STA. The command CMD includes, for example, commands for causing the sequencer 14 to execute a read operation, a write operation, an erase operation, or the like, respectively. The address information ADD includes, for example, a block address, a page address, and a column address. For example, the block address, the page address, and the column address are used to select a block BLK, a word line, and a bit line, respectively. The status information STA is updated based on control by the sequencer 14 and transferred to the input/output circuit 11.

The sequencer 14 controls the entire operation of the semiconductor memory device 10. For example, the sequencer 14 controls the voltage generator 15, the row decoder 17, the sense amplifier module 18, and the like and executes the read operation, the write operation, the erase operation, and the like based on the command CMD stored in the register 13.

The voltage generator 15 receives a voltage input from the outside of the semiconductor memory device 10, adjusts, boosts, and steps down the voltage, and outputs the voltage. The voltage generated by the voltage generator 15 is appropriately transferred to the sequencer 14, the memory cell array 16, the row decoder 17, the sense amplifier module 18, and the like. The voltage generator 15 includes a charge pump circuit 152. The charge pump circuit 152 boosts the voltage input to the voltage generator 15. A detailed configuration of the voltage generator 15 will be described later.

The memory cell array 16 includes a plurality of blocks BLK, a plurality of bit lines, and a plurality of word lines. The blocks BLK are a set of a plurality of memory cell transistors capable of storing data in a nonvolatile manner. In the example illustrated in FIG. 2, the memory cell array 16 includes four blocks BLK0 to BLK3. The blocks BLK are used, for example, as erase units of the data DAT in the erase operation. Each of the memory cell transistors is associated with a set of a bit line and a word line.

The row decoder 17 selects, based on the block address stored in the register 13, the corresponding one block BLK in the memory cell array 16. The row decoder 17 further selects the word line in the selected block BLK based on, for example, the page address stored in the register 13. The row decoder 17 applies the voltage generated by the voltage generator 15 to the selected word line in the selected block BLK.

The sense amplifier module 18 includes sense amplifiers capable of determining data based on a voltage of the associated bit line, latch circuits that temporarily store data, and the like. The sense amplifier module 18 selects the bit line based on the column address stored in the register 13. In the write operation, the sense amplifier module 18 applies a desired voltage generated by the voltage generator 15 to each bit line in accordance with the write data DAT received from the input/output circuit 11. In addition, the sense amplifier module 18 determines data stored in a memory cell transistor based on the magnitude of the voltage of the selected bit line in the read operation. Thereafter, the sense amplifier module 18 transfers the determination result as read data DAT to the input/output circuit 11.

The power supply pad group 19 includes a plurality of pads PD1 to PD5. The plurality of pads PD1 to PD5 are coupled to external power supplies having voltages VCC, VCCH, VPP, VCCQ, and VSS, respectively.

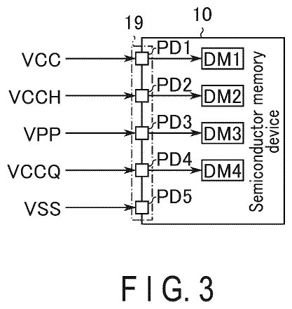

FIG. 3 is a block diagram illustrating an example of a power supply configuration in the semiconductor memory device according to the first embodiment. As illustrated in FIG. 3, the semiconductor memory device 10 according to the first embodiment includes power supply domains DM1, DM2, DM3, and DM4.

The power supply domain DM1 is a power supply domain coupled to the pad PD1. The power supply domain DM1 includes, for example, the sequencer 14, the row decoder 17, the sense amplifier module 18, and the like. The sequencer 14, the row decoder 17, the sense amplifier module 18, and the like are referred to as peripheral circuits as opposed to the memory cell array 16. The voltage VCC is supplied to the power supply domain DM1 via the pad PD1. The voltage VCC is, for example, a power supply voltage of about 2.35 V to 2.8 V. As a more specific example, the voltage VCC has a voltage value of about 2.5 V. The voltage VCC is provided as an operation power supply of the semiconductor memory device 10, and is used for driving the peripheral circuits, for example.

The power supply domain DM2 is a power supply domain coupled to the pad PD2. The power supply domain DM2 includes, for example, the charge pump circuit 152. The voltage VCCH is supplied to the power supply domain DM2 via the pad PD2. The voltage VCCH indicates a voltage value higher than the voltage VCC, and is, for example, a power supply voltage of about 2.7 V to 3.6 V. As a more specific example, the voltage VCCH has a voltage value of about 3.3 V. The voltage VCCH is a power supply voltage for generating a voltage to be applied to the memory cell array 16 during a read operation, a write operation, and an erase operation. By boosting the voltage VCCH in the charge pump circuit 152, a voltage of a predetermined magnitude corresponding to various operations is generated.

The power supply domain DM3 is a power supply domain coupled to the pad PD3. The power supply domain DM3 includes, for example, some peripheral circuits. The voltage VPP is supplied to the power supply domain DM3 via the pad PD3. The voltage VPP indicates a voltage value higher than the voltage VCCH, and has a voltage value of, for example, about 6 V to 12 V. As a more specific example, the voltage VPP has a voltage value of about 12 V. The voltage VPP may have a voltage value higher than 12 V. The power supply domain DM3 is appropriately used, for example, when a high voltage is required in the peripheral circuits. Note that the power supply domain DM3 is a power supply domain additionally provided according to a use environment. That is, the voltage VPP may not be input to the semiconductor memory device 10, and the pad PD3 and the power supply domain DM3 may not be provided in the semiconductor memory device 10.

The power supply domain DM4 is a power supply domain coupled to the pad PD4. The power supply domain DM4 includes, for example, the input/output circuit 11 and the logic controller 12. The voltage VCCQ is supplied to the power supply domain DM4 via the pad PD4. The voltage vccQ indicates a voltage value lower than the voltage VCC, and has a voltage value of, for example, about 1.2 V to 1.8 V. The voltage VCCQ is transferred to, for example, the input/output circuit 11 and the logic controller 12, and is used for transmission and reception of signals by the semiconductor memory device 10 and the memory controller 20.

The voltage VSS is input to the pad PD5. The voltage VSS is a ground voltage, and has, for example, a voltage value of 0 V.

Note that the configuration of the power supply domains DM1 to DM4 is an example, and the power supply domains DM1 to DM4 may include components other than the above-described components in the semiconductor memory device 10.

### 1.1.5 Memory Cell Array

Next, a configuration of the memory cell array 16 according to the first embodiment will be described.

### 1.1.5.1 Circuit Configuration

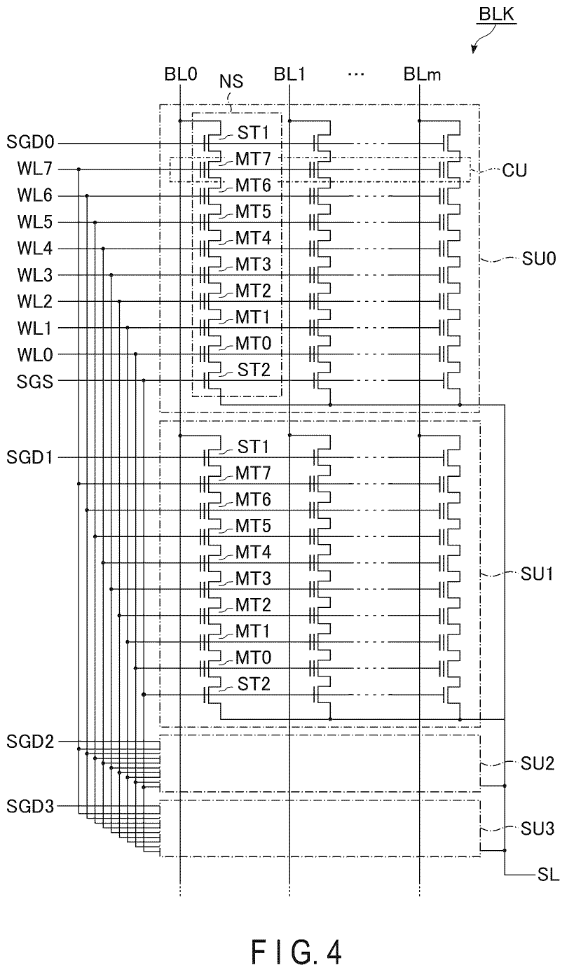

FIG. 4 is a circuit diagram illustrating an example of a circuit configuration of the memory cell array according to the first embodiment. FIG. 4 illustrates one block BLK among the plurality of blocks BLK included in the memory cell array 16. As illustrated in FIG. 4, the block BLK includes, for example, four string units SU0 to SU3. The number of string units SU is arbitrary.

Each of the string units SU includes a plurality of NAND strings NS respectively associated with bit lines BL0 to BLm (m is an integer greater than or equal to 1). Each of the NAND strings NS includes, for example, eight memory cell transistors MT0 to MT7 and select transistors ST1 and ST2. Each of the memory cell transistors MT includes a control gate and a charge storage film, and stores data in a nonvolatile manner based on the amount of charges in the charge storage film. Each of the select transistors ST1 and ST2 is used to select a string unit SU during various operations.

In each of the NAND strings NS, the memory cell transistors MT0 to MT7 are coupled in series in this order. A drain of the select transistor ST1 is coupled to the associated bit line BL, and a source of the select transistor ST1 is coupled to a drain of the memory cell transistor MT7. A drain of the select transistor ST2 is coupled to a source of the memory cell transistor MT0, and a source of the select transistor ST2 is coupled to a source line SL.

The control gates of the memory cell transistors MT0 to MT7 in the same block BLK are coupled to word lines WL0 to WL7, respectively. Gates of the select transistors ST1 in the string units SU0 to SU3 are coupled to select gate lines SGD0 to SGD3, respectively. Gates of the select transistors ST2 are coupled to a select gate line SGS.

Different column addresses are assigned to the bit lines BL0 to BLm. Each of the bit lines BL is shared by the NAND strings NS to which the same column address is assigned in the plurality of blocks BLK. Each of the word lines WL0 to WL7 is provided for each block BLK. The source line SL is shared by the plurality of blocks BLK, for example.

A set of a plurality of memory cell transistors MT coupled to a common word line WL in one string unit SU is referred to as, for example, a cell unit CU. For example, the storage capacity of the cell unit CU including the memory cell transistors MT each storing 1-bit data is defined as “1-page data”. The cell unit CU may have a storage capacity for two-page data or more according to the number of bits of data stored in the memory cell transistors MT.

Note that the circuit configuration of the memory cell array 16 included in the semiconductor memory device 10 according to the present embodiment is not limited to the above description. For example, the number of string units SU included in each of the blocks BLK can be designed to any number. The number of memory cell transistors MT and the number of select transistors ST1 and ST2 included in each of the NAND strings NS can be designed to any numbers.

### 1.1.5.2 Memory Structure

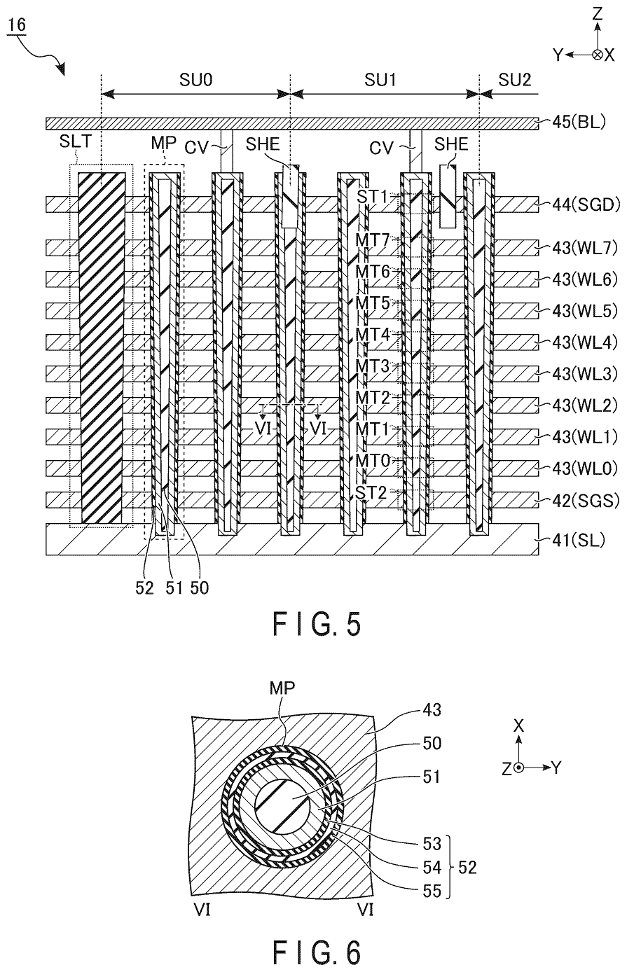

FIG. 5 is a cross-sectional view illustrating an example of a structure of the memory cell array according to the first embodiment. The memory cell array 16 according to the first embodiment has a stacked interconnect structure in which the source line SL, the select gate lines SGS and SGD, and the word lines WL0 to WL7 are stacked apart from each other. In FIG. 5, an X direction is a direction in which the word lines WL extend. A Y direction is a direction in which the bit lines BL extend. A Z direction is a direction in which layers are stacked in the stacked interconnect structure.

As illustrated in FIG. 5, the memory cell array 16 has a structure in which an interconnect layer 41, an interconnect layer 42, a plurality of interconnect layers 43, an interconnect layer 44, and an interconnect layer 45 are stacked in this order while being separated from each other. The interconnect layer 41 corresponds to the source line SL and contains, for example, polysilicon. The interconnect layer 42 corresponds to the select gate line SGS, and contains, for example, tungsten (W) or molybdenum (Mo). The plurality of interconnect layers 43 correspond to the word lines WL0 to WL7, respectively, and contain, for example, tungsten or molybdenum. The interconnect layer 44 corresponds to the select gate lines SGD and contains, for example, tungsten or molybdenum. The interconnect layer 45 corresponds to the bit lines BL and contains, for example, copper (Cu). Although not illustrated, the interconnect layers 41 to 45 are embedded with an insulator containing, for example, silicon oxide (SiO), and are electrically insulated from each other.

The memory cell array 16 includes a plurality of memory pillars MP, a plurality of insulating members SLT and SHE, and a plurality of contacts CV.

Each of the memory pillars MP extends through the interconnect layer 42, the plurality of interconnect layers 43, and the interconnect layer 44 in the Z direction, and has a lower surface in contact with the interconnect layer 41. Portions where the memory pillars MP intersect the interconnect layer 42 function as the select transistors ST2. Portions where the memory pillars MP intersect the plurality of interconnect layers 43 function as the memory cell transistors MT0 to MT7, respectively. Portions where the memory pillars MP intersect the interconnect layer 44 function as the select transistors ST1.

Each of the memory pillars MP includes a core film 50, a semiconductor film 51, and a stacked film 52. The core film 50 extends along the Z direction. The core film 50 includes, for example, an insulator such as silicon oxide. The semiconductor film 51 covers a periphery of the core film 50. The semiconductor film 51 is used as a channel (current path) for the memory cell transistors MT0 to MT7 and the select transistors ST1 and ST2. At a lower end of each of the memory pillars MP, a portion of the semiconductor film 51 is in contact with and electrically coupled to the interconnect layer 41. The semiconductor film 51 contains, for example, silicon (Si). The stacked film 52 covers a side surface of the semiconductor film 51 except for a portion where the semiconductor film 51 and the interconnect layer 41 are in contact with each other.

FIG. 6 is a cross-sectional view taken along line VI-VI in FIG. 5, illustrating an example of a cross-sectional structure of the memory pillar in the memory cell array according to the first embodiment. More specifically, FIG. 6 illustrates the cross-sectional structure of the memory pillar MP in a layer including the interconnect layer 43. As illustrated in FIG. 6, the stacked film 52 includes, for example, a tunnel insulating film 53, a charge storage film 54, and a block insulating film 55.

In the cross section including the interconnect layer 43, the core film 50 is provided, for example, at a central portion of the memory pillar MP. The semiconductor film 51 surrounds a side surface of the core film 50. The tunnel insulating film 53 surrounds the side surface of the semiconductor film 51. The charge storage film 54 surrounds a side surface of the tunnel insulating film 53. The block insulating film 55 surrounds a side surface of the charge storage film 54. The interconnect layer 43 surrounds a side surface of the block insulating film 55.

Each of the tunnel insulating film 53 and the block insulating film 55 contains, for example, silicon oxide. The charge storage film 54 includes, for example, silicon nitride (SiN). With this configuration, the memory pillar MP can function as one NAND string NS.

The insulating member SLT is formed in a plate shape extending in the X direction and the Z direction, and divides the interconnect layer 42, the plurality of interconnect layers 43, and the interconnect layer 44 in the Y direction. Each of regions divided by the insulating member SLT corresponds to a corresponding one of the blocks BLK. The insulating member SLT contains, for example, silicon oxide.

The plurality of insulating members SHE are formed in a plate shape extending in the X direction and the Z direction, and divide the interconnect layer 44 in the Y direction. The regions divided by the plurality of insulating members SLT and SHE correspond to the select gate lines SGD0 to SGD3, respectively. The insulating members SHE contain, for example, silicon oxide.

The contact CV is a columnar contact extending in the Z direction. The contact CV has a lower surface in contact with the semiconductor film 51 of the corresponding memory pillar MP and an upper surface in contact with the corresponding interconnect layer 45 so as to electrically connect the semiconductor film 51 and the interconnect layer 45.

### 1.1.6 Voltage Generator

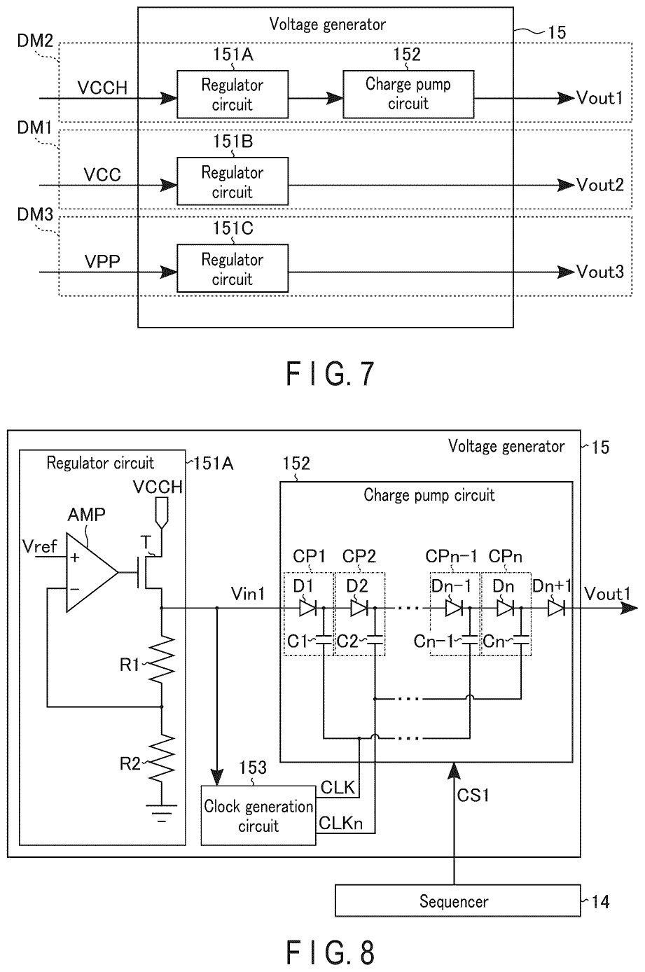

FIG. 7 is a block diagram illustrating an example of a configuration of the voltage generator according to the first embodiment. As illustrated in FIG. 7, the voltage generator 15 includes a plurality of regulator circuits 151A, 151B, and 151C, and a charge pump circuit 152.

The plurality of regulator circuits 151A, 151B, and 151C are circuits that smooth an input voltage and output a constant voltage and a constant current. The regulator circuits 151A, 151B, and 151C are included in the power supply domains DM2, DM1, and DM3, respectively. A power supply voltage input from the outside may slightly fluctuate. Each of the regulator circuits 151A, 151B, and 151C can reduce fluctuation of the power supply voltage and output a constant voltage and a constant current by stepping down the input power supply voltage to a predetermined voltage.

The charge pump circuit 152 boosts and outputs an input voltage. The charge pump circuit 152 is included in the power supply domain DM2. The voltage boosted by the charge pump circuit 152 is transferred to the row decoder 17 and the sense amplifier module 18 and applied to the memory cell array 16, whereby reading, writing, and erasing of data stored in the memory cell transistors MT are performed.

The regulator circuit 151A is coupled to the pad PD2, and the voltage VCCH is input to the regulator circuit 151A. The regulator circuit 151A regulates the voltage VCCH and outputs the regulated voltage as an input voltage Vin1 to be input to the charge pump circuit 152. The charge pump circuit 152 boosts the input voltage Vin1 and outputs an output voltage Vout1. The output voltage Vout1 is transferred to the row decoder 17 and the sense amplifier module 18.

The regulator circuit 151B is coupled to the pad PD1, and the voltage VCC is input to the regulator circuit 151B. The regulator circuit 151B regulates the voltage VCC and outputs an output voltage Vout2. The regulator circuit 151C is coupled to the pad PD3, and the voltage VPP is input to the regulator circuit 151C. The regulator circuit 151C regulates the voltage VPP and outputs an output voltage Vout3. The output voltages Vout2 and Vout3 are used for driving the peripheral circuits. Which one of the output voltages Vout2 and Vout3 is used as a drive voltage of the peripheral circuits is appropriately determined based on the characteristics of the peripheral circuits. In general, the output voltage Vout3 is used when a voltage higher than the output voltage Vout2 is required.

FIG. 8 is a circuit diagram illustrating an example of a circuit configuration of the voltage generator according to the first embodiment. FIG. 8 illustrates a circuit configuration of the regulator circuit 151A and the charge pump circuit 152 that generate the output voltage Vout1. The voltage generator 15 further includes a clock generation circuit 153.

The regulator circuit 151A includes a transistor T, an amplifier AMP, and resistors R1 and R2.

The transistor T is, for example, an n-type metal-oxide-semiconductor field-effect transistor (MOSFET). The transistor T includes a drain terminal to which a voltage VCCH is input, a source terminal from which an output voltage is output, and a gate terminal to which a control signal is input. The output voltage output from the source terminal is a voltage regulated to a predetermined voltage value. The output voltage output from the source terminal is input to the charge pump circuit 152 and the clock generation circuit 153 as the input voltage Vin1.

The resistors R1 and R2 are coupled in series between the source terminal of the transistor T and a ground terminal. The resistors R1 and R2 divide the output voltage. A voltage at a coupling point where the resistors R1 and R2 are coupled is input to the amplifier AMP as a feedback voltage.

The amplifier AMP includes a non-inverting input terminal, an inverting input terminal, and an output terminal. A reference voltage Vref is input to the non-inverting input terminal of the amplifier AMP, and the feedback voltage is input to the inverting input terminal of the amplifier AMP. The amplifier AMP outputs a control signal corresponding to the difference between the reference voltage Vref and the feedback voltage to the gate terminal of the transistor T. The amplifier AMP controls the transistor T such that the feedback voltage becomes equal to the reference voltage Vref, thereby changing the output voltage to be output from the source terminal of the transistor T.

The regulator circuit 151A is configured such that a range in which the voltage is stepped down is as small as possible. That is, resistance values of the resistors R1 and R2 are set such that the difference between the voltage VCCH input from the pad PD2 and the input voltage Vin1 to be input to the charge pump circuit 152 and the clock generation circuit 153 is as small as possible. Therefore, the input voltage Vin1 may be regarded to be substantially equal to the voltage VCCH.

Although not illustrated, each of the regulator circuits 151B and 151C also has a circuit configuration similar to that of the regulator circuit 151A illustrated in FIG. 8. Each of the regulator circuits 151B and 151C may include, for example, a variable resistor, and may have a circuit configuration in which a range in which a voltage is stepped down can be freely adjusted under control by the sequencer 14.

The clock generation circuit 153 is included in the power supply domain DM2. The clock generation circuit 153 generates a clock signal CLK and an inverted clock signal CLKn by causing the input voltage Vin1 output from the regulator circuit 151A to oscillate. The inverted clock signal CLKn is obtained by inverting the clock signal CLK. The magnitude of the voltage when the clock signal CLK and the inverted clock signal CLKn are at an “H” level is equivalent to the input voltage Vin1, and the magnitude of the voltage when the clock signal CLK and the inverted clock signal CLKn are at an “L” level is equivalent to the voltage VSS.

The charge pump circuit 152 includes n+1 diodes D1 to Dn+1 and n capacitors C1 to Cn (n is an integer greater than or equal to 1). One charge pump unit CP is formed of one diode among the diodes and one capacitor among the capacitors. Specifically, a charge pump unit CP1 includes a diode D1 and a capacitor C1. A charge pump unit CPn includes a diode Dn and a capacitor Cn. That is, it can be said that the charge pump circuit 152 includes n charge pump units CP1 to CPn and the diode Dn+1. In the following description, a case where n is an even number will be described, but n may be an odd number.

The diodes D1 to Dn+1 are configured, for example, by coupling a drain terminal and a gate terminal of an n-type MOSFET (diode connection). The diodes D1 to Dn+1 are coupled in series.

First ends of the capacitors C1 to Cn are coupled to nodes between the corresponding diodes D1 to Dn and the diodes D2 to Dn+1 at the subsequent stages. Specifically, the first end of the capacitor C1 is coupled to the node between the diode D1 and the diode D2. The first end of the capacitor Cn is coupled to the node between the diode Dn and the diode Dn+1. Second ends of the capacitors C1 to Cn are coupled to the clock generation circuit 153. The clock signal CLK is input to the second ends of the capacitors C1, C3, . . . , and Cn−1. The inverted clock signal CLKn is input to the second ends of the capacitors C2, C4, . . . , and Cn.

The input voltage Vin1 is input to an input terminal of the diode D1. At the timing when the clock signal CLK is at an “L” level and the inverted clock signal CLKn is at an “H” level, a voltage equivalent to the input voltage Vin1 is output from an output terminal of the diode D1, and the capacitor C1 is charged at the first end of the capacitor C1. Next, at the timing when the clock signal CLK is at an “H” level and the inverted clock signal CLKn is at an “L” level, the voltage at the first end of the capacitor C1 is boosted to 2×Vin1 and is discharged from the first end of the capacitor C1 due to the effect of a change in the voltage applied to the second end of the capacitor C1 from an “L” level to an “H” level. The voltage discharged from the first end of the capacitor C1 is input to an input terminal of the diode D2 at the next stage. As described above, the capacitors C1 to Cn repeat charging and discharging in accordance with the clock signal CLK and the inverted clock signal CLKn, whereby the output voltage Vout1 higher than the input voltage Vin1 input to the charge pump circuit 152 is generated and output.

The magnitude of the output voltage Vout1 of the charge pump circuit 152 is determined in accordance with the number of stages of the charge pump units CP coupled in series. Specifically, when the number of stages of the charge pump units CP is N, the maximum output voltage of the charge pump circuit 152 is represented by (N+1)×Vin1 using the input voltage Vin1 (N is an integer satisfying 1≤N≤n). That is, the output voltage Vout1 can be increased as the number of stages of the charge pump units CP is increased. The charge pump circuit 152 changes the number of stages of the charge pump units CP in accordance with the control signal CS1 from the sequencer 14, thereby generating and outputting a plurality of voltages to be used for the read operation, the write operation, and the erase operation. The control signal CS1 is a control signal for controlling the number of stages of the charge pump units CP in the charge pump circuit 152. In other words, the charge pump circuit 152 rearranges the charge pump units CP based on the control signal CS1 from the sequencer 14 to generate a voltage having a magnitude corresponding to various operations.

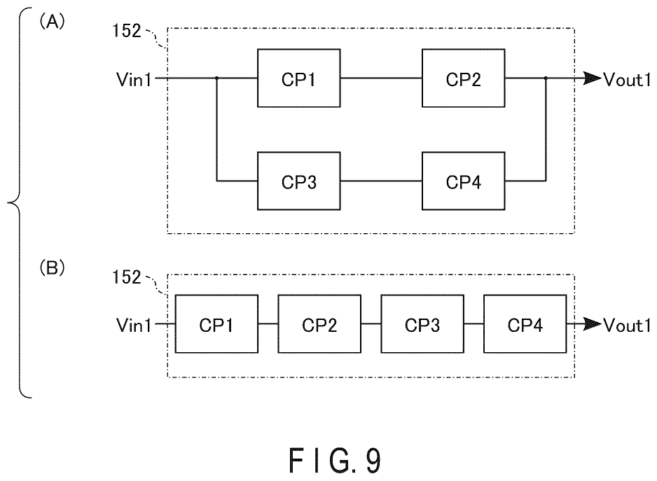

FIG. 9 is a block diagram illustrating an example of changing the number of stages of the charge pump units in the charge pump circuit included in the voltage generator according to the first embodiment. Part (A) of FIG. 9 illustrates an example in which the number of stages of the charge pump units in the charge pump circuit 152 is 2. Part (B) of FIG. 9 illustrates an example in which the number of stages of the charge pump units in the charge pump circuit 152 is 4.

When a maximum output voltage that is three times higher than the input voltage Vin1 is to be output, as illustrated in part (A) of FIG. 9, the charge pump units CP are rearranged such that the charge pump units CP1 and CP2 are coupled in series, the charge pump units CP3 and CP4 are coupled in series, and the charge pump units CP1 and CP2 are coupled in parallel to the charge pump units CP3 and CP4.

The charge pump unit CP1 boosts the input voltage Vin1 and outputs a voltage of 2×Vin1 to the charge pump unit CP2. The charge pump unit CP2 boosts the input voltage of 2×Vin1 and outputs a voltage of 3×Vin1. The charge pump unit CP3 boosts the input voltage Vin1 and outputs a voltage of 2×Vin1 to the charge pump unit CP4. The charge pump unit CP4 boosts the input voltage of 2×Vin1 and outputs a voltage of 3×Vin1. Since the charge pump units CP1 and CP2 are coupled in parallel to the charge pump units CP3 and CP4, a voltage 3×Vin1 obtained by tripling the input voltage Vin1 is output as the maximum output voltage from the charge pump circuit 152. In the configuration in which the charge pump units CP1 and CP2 are coupled in parallel to the charge pump units CP3 and CP4, the current output from the charge pump circuit 152 is about 2 times larger than that in the configuration in which only the charge pump units CP1 and CP2 are coupled in series.

When a maximum output voltage that is five times higher than the input voltage Vin1 is to be output, as illustrated in part (B) of FIG. 9, the charge pump units CP are rearranged such that the charge pump units CP1, CP2, CP3, and CP4 are coupled in series.

The charge pump unit CP1 boosts the input voltage Vin1 and outputs a voltage of 2×Vin1 to the charge pump unit CP2. The charge pump unit CP2 boosts the input voltage of 2×Vin1 and outputs a voltage of 3×Vin1. The charge pump unit CP3 boosts the input voltage of 3×Vin1 and outputs a voltage of 4×Vin1. The charge pump unit CP4 boosts the input voltage of 4×Vin1 and outputs a voltage of 5×Vin1. Therefore, the voltage 5×Vin1 obtained by multiplying the input voltage Vin1 by 5 is output from the charge pump circuit 152 as the maximum output voltage.

In practice, the output voltage Vout1 in the case of the number N of stages is lower than the maximum output voltage (N+1)×Vin1 due to the effect of a voltage drop caused by an output current Iout1 output from the charge pump circuit 152. The magnitude of the output current Iout1 output from the charge pump circuit 152 is expressed by the following Equation (1).

$$Iout 1 = M \times C \frac{( N + 1 ) Vin 1 - Vout 1}{N \times Tclk} \qquad ( 1 )$$

In this case, N is the number of stages of the charge pump units CP coupled in series, M is the number of parallel couplings of the charge pump units CP in a case where the number of stages is N, C is the capacitance of the capacitors C1 to Cn, and Tclk is the period of each of the clock signal CLK and the inverted clock signal CLKn. From Equation (1), the output current Iout1 of the charge pump circuit 152 is determined in accordance with the number N of stages and the number M of parallel couplings of the charge pump units CP.

Although FIG. 9 illustrates an example in which the number n of charge pump units CP in the charge pump circuit 152 is four, this is an example, and a large number of combinations of the number N of stages and the number M of parallel couplings can be considered depending on the number n of charge pump units CP. The number N of stages of the charge pump units CP is arbitrary as long as the number N is an integer satisfying 1≤N≤n, and the number M of parallel couplings of the charge pump units CP is arbitrary as long as the number M is an integer satisfying 1≤M×N≤n.

### 1.2 Effect

The semiconductor memory device 10 according to the first embodiment can improve power efficiency. This effect will be described in detail below.

To perform the read operation, the write operation, and the erase operation in the semiconductor memory device 10, a voltage corresponding to various operations is applied to the word lines WL in the memory cell array 16, and the word lines WL are charged. For example, during the read operation, a voltage VREAD is applied to all word lines WL (non-selected word lines) other than a read target. The voltage VREAD is a voltage having a magnitude that turns on the memory cell transistors MT regardless of data stored in the memory cell transistors MT, and is, for example, about 6.0 V.

In recent years, the number of word lines of a memory cell array included in a semiconductor memory device has increased in order to reduce the cost of the semiconductor memory device. In the read operation, since the voltage VREAD is applied to all the non-selected word lines, the power consumption in the read operation also increases as the number of word lines is increased. Therefore, the improvement of the power efficiency of the semiconductor memory device is required.

Further, in the read operation, it is required to quickly read data stored in the memory cell transistors. For this purpose, the voltages of all the non-selected word lines are required to quickly rise to the voltage VREAD. Therefore, it is desirable that a current for charging the non-selected word lines be large.

For example, in a case where the memory system 3 is an SSD coupled to a personal computer, the memory system 3 may have both a power supply that supplies a power supply voltage of, for example, about 2.35 V to 2.8 V corresponding to the voltage VCC, and a power supply that supplies a power supply voltage of, for example, about 2.7 V to 3.6 V corresponding to the voltage VCCH for uses not described in the present specification. Similarly, the transistors included in the semiconductor memory device 10 may also have not only a withstand voltage characteristic for the voltage VCC but also a withstand voltage characteristic for the voltage VCCH. By configuring the memory system 3 to supply the power supply voltage corresponding to the voltage VCCH to the pad PD2 of the semiconductor memory device 10, it is possible to improve the power efficiency of the semiconductor memory device 10 without changing the withstand voltage characteristics of the transistors disposed in the semiconductor memory device 10.

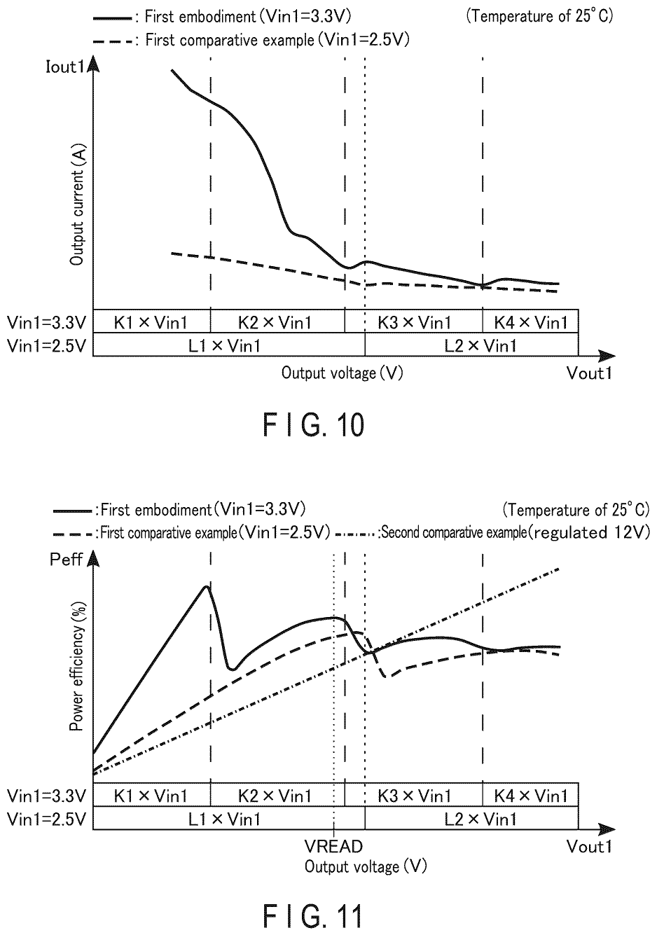

FIG. 10 is a graph illustrating a relationship between an output voltage and an output current in the voltage generator included in the semiconductor memory device according to the first embodiment. FIG. 11 is a graph illustrating a relationship between the output voltage and power efficiency in the voltage generator included in the semiconductor memory device according to the first embodiment. FIGS. 10 and 11 illustrate the relationship between the output voltage and the output current and the relationship between the output voltage and the power efficiency in the configuration in which the charge pump circuit is optimized in accordance with the output voltage.

In each of FIGS. 10 and 11, a case where the charge pump circuit 152 boosts a voltage of 3.3 V (corresponding to VCCH) to generate a desired output voltage Vout1 in the first embodiment is indicated by a solid line. In this case, it may be considered that a range in which the voltage is stepped down in the regulator circuit 151A is sufficiently small and that the input voltage Vin1 of the charge pump circuit 152 is substantially equal to the voltage VCCH. That is, Vin1=VCCH. As a first comparative example, a case where a charge pump circuit boosts a voltage of 2.5 V (corresponding to VCC) to generate a desired output voltage Vout1 (that is, Vin1=VCC) is indicated by broken lines. In the charge pump circuit according to the first comparative example, similarly to the first embodiment, the number of stages of charge pump units is changed by rearranging the charge pump units, and a desired output voltage is generated. In addition, in FIG. 11, as a second comparative example, a case where a voltage of 12 V (corresponding to VPP) is regulated using a regulator circuit to generate a desired output voltage Vout1 is indicated by a one-dot chain line. In the second comparative example, the desired output voltage is generated by stepping down the input voltage using the regulator circuit including a variable resistor. FIGS. 10 and 11 illustrate values in a case where the temperature is 25° C. in all of the first embodiment, the first comparative example, and the second comparative example.

In FIGS. 10 and 11, K indicates the number of stages of the charge pump units CP in the charge pump circuit 152 according to the first embodiment. In the voltage range illustrated in FIGS. 10 and 11, the stage numbers K of the charge pump units CP in the charge pump circuit 152 according to the first embodiment include K1, K2, K3, and K4. K1, K2, K3, and K4 are each a positive integer, and satisfy K1<K2<K3<K4. L represents the number of stages of the charge pump units in the charge pump circuit according to the first comparative example. In the voltage range illustrated in FIGS. 10 and 11, the number L of stages of the charge pump units in the charge pump circuit according to the first comparative example includes L1 and L2. L1 and L2 are each a positive integer and satisfy L1<L2.

The maximum output voltage of the charge pump circuit is expressed by (N+1)×Vin1 where N is the number of stages of the charge pump units in the charge pump circuit. In general, when the input voltage Vin1 increases, it is possible to decrease the number N of stages for generating a desired output voltage Vout1. A voltage of 3.3 V is input as the input voltage Vin1 to the charge pump circuit 152 according to the first embodiment. On the other hand, a voltage of 2.5 V is input as the input voltage Vin1 to the charge pump circuit according to the first comparative example. Therefore, regardless of the desired magnitude of the output voltage Vout1, it can be said that the number K of stages of the charge pump units CP of the charge pump circuit 152 according to the first embodiment for generation of the output voltage Vout1 is equal to or less than the number L of stages of the charge pump units of the charge pump circuit according to the first comparative example for generation of the output voltage Vout1 (K≤L).

As indicated by Equation (1), the output current Iout1 of the charge pump circuit 152 is determined in accordance with the number N of stages and the number M of parallel couplings of the charge pump units CP. The charge pump circuit 152 can output a larger output current Iout1 by changing the number N of stages and the number M of parallel couplings of the charge pump units CP based on a desired output voltage Vout1. As a result of optimizing the number N of stages and the number M of parallel couplings of the charge pump units CP in this manner, as illustrated in FIG. 10, the output current Iout1 with respect to the output voltage Vout1 of the charge pump circuit 152 according to the first embodiment can be larger than the output current Iout1 with respect to the output voltage Vout1 of the charge pump according to the first comparative example. Therefore, for example, during the read operation, the non-selected word lines can be charged more quickly than in the first comparative example. As a result, the time required for the read operation can be shortened.

The current efficiency n of the charge pump circuit 152 is expressed by the following Equation (2).

$$η = \frac{I out 1}{Iin 1} ∝ \frac{1}{N + 1} \qquad ( 2 )$$

Where, Iin1 represents an input current input to the charge pump circuit 152, and N represents the number of stages of the charge pump units CP. That is, the current efficiency n of the charge pump circuit 152 is inversely proportional to N+1.

In addition, the power efficiency Peff of the charge pump circuit 152 is expressed by the following Equation (3).

$$P e f f = \frac{Vout 1 \times Iout 1}{Vin 1 \times Iin 1} = η \frac{Vout 1}{Vin 1} \qquad ( 3 )$$

In Equation (3), both the input voltage Vin1 and the output voltage Vout1 are variables set in advance for the operation of the semiconductor memory device 10. Therefore, the power efficiency Peff of the charge pump circuit 152 is proportional to the current efficiency n of the charge pump circuit 152, that is, inversely proportional to N+1.

In the regulator circuit according to the second comparative example, in a case where a high voltage is regulated to generate a desired output voltage Vout1, the input current Iin1 and the output current Iout1 have substantially the same value. Therefore, the power efficiency Peff of the regulator circuit according to the second comparative example is proportional to the ratio of the output voltage Vout1 to the input voltage Vin1.

As described above, as illustrated in FIG. 11, the power efficiency Peff with respect to the output voltage Vout of the charge pump circuit 152 according to the first embodiment takes a value higher than the power efficiency Peff with respect to the output voltage Vout1 of the charge pump according to the first comparative example except for some cases. In the regulator circuit according to the second comparative example, the power efficiency Peff decreases as the output voltage Vout1 decreases. Therefore, for example, in a method of generating the voltage VREAD using the charge pump circuit 152 according to the first embodiment, the power efficiency Peff can be the highest. That is, the power efficiency of the semiconductor memory device 10 can be improved.

### 1.3 Modifications

The semiconductor memory device 10 according to the first embodiment described above can be variously modified.

For example, in the first embodiment, the voltage VCCH is used for generating a voltage to be applied to the memory cell array 16, but may be used for other purposes. For example, the power supply domain DM2 may include some of the peripheral circuits, and the voltage VCCH may be input as a drive voltage of either one or both of the row decoder 17 and the sense amplifier module 18. By replacing either one or both of the power supply voltages of the row decoder 17 and the sense amplifier module 18 with the voltage VCCH, the drive voltages of various circuits are increased, and it is possible to reduce malfunctions due to voltage drop, so that the reliability of the memory cell array 16 can be improved.

The voltage VCCH input to the pad PD2 is input to the charge pump circuit 152 and the clock generation circuit 153 via the regulator circuit 151A in the voltage generator 15, but the present embodiment is not limited thereto. For example, input terminals of the charge pump circuit 152 and the clock generation circuit 153 may be directly coupled to the pad PD2.

In addition, the semiconductor memory device 10 may include a charge pump circuit different from the charge pump circuit 152 that is included in the power supply domain DM1 and coupled to the pad PD1. In this case, as the voltage applied to the memory cell array 16, an optimum voltage is appropriately selected from the voltage generated from the power supply domain DM2 and the voltage generated from the power supply domain DM1 in accordance with various operations to be executed by the semiconductor memory device 10.

### 2. Second Embodiment

A semiconductor memory device according to a second embodiment will be described below. In the following description, description of configurations equivalent to those in the first embodiment will be omitted, and configurations different from those in the first embodiment will be mainly described.

### 2.1 Configuration

### 2.1.1 Power Supply Configuration

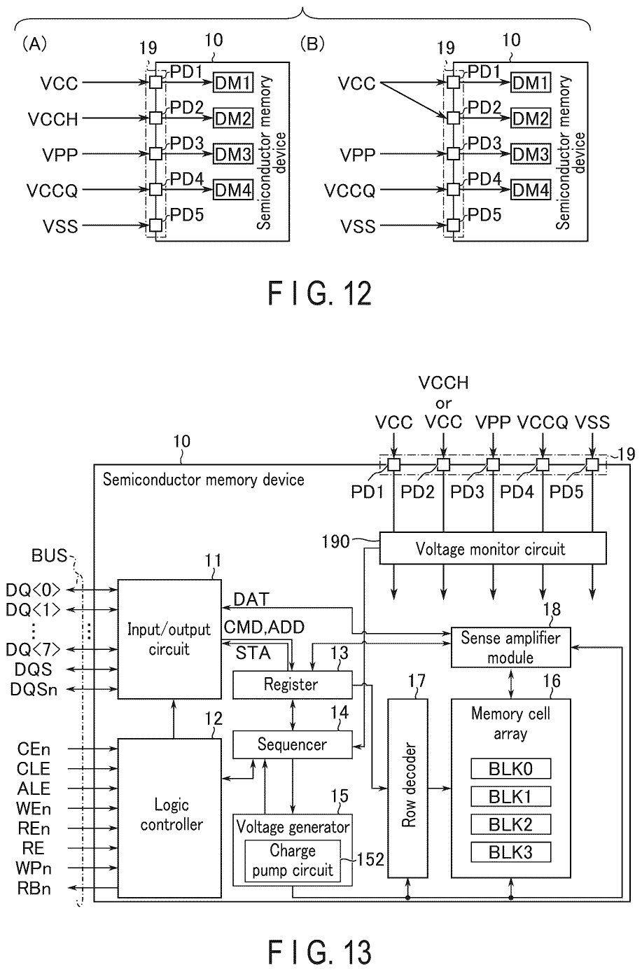

FIG. 12 is a block diagram illustrating an example of a power supply configuration in the semiconductor memory device according to the second embodiment.

In a memory system 3 according to the second embodiment, for example, a power supply voltage of about 2.7 V to 3.6 V corresponding to a voltage VCCH may not be supplied to the semiconductor memory device 10. Part (A) of FIG. 12 illustrates a case where the voltage VCCH is supplied to the semiconductor memory device 10, and part (B) of FIG. 12 illustrates a case where the voltage VCCH is not supplied to the semiconductor memory device 10.

As illustrated in part (A) of FIG. 12, in a case where the voltage VCCH is supplied to the semiconductor memory device 10, a voltage VCCH of, for example, about 2.7 V to 3.6 V is input to a pad PD2 of the semiconductor memory device 10 as in the first embodiment.

On the other hand, as illustrated in part (B) of FIG. 12, in a case where the voltage VCCH is not supplied to the semiconductor memory device 10, a voltage VCC of, for example, about 2.35 V to 2.8 V is input to the pad PD2 of the semiconductor memory device 10, similarly to a pad PD1.

As described above, since the voltage input to the pad PD2 may fluctuate, a power supply voltage in a power supply domain DM2 coupled to the pad PD2 in the semiconductor memory device 10 may also fluctuate.

### 2.1.2 Semiconductor Memory Device

FIG. 13 is a block diagram illustrating an example of a configuration of the semiconductor memory device according to the second embodiment. As illustrated in FIG. 13, the semiconductor memory device 10 according to the second embodiment further includes a voltage monitor circuit 190.

The voltage monitor circuit 190 is coupled to each of the pads PD1 to PD5. The voltage monitor circuit 190 monitors the magnitude of a power supply voltage input to each of the pads PD1 to PD5, and outputs voltage value information of each power supply voltage to a sequencer 14. In particular, it is determined whether the voltage input to the pad PD2 is the voltage VCCH or the voltage VCC.

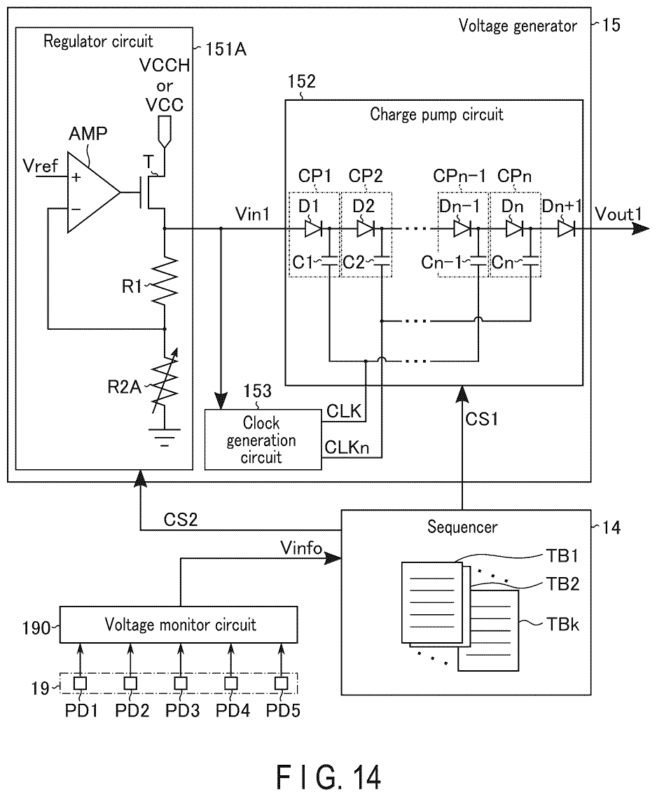

2.1.3 Voltage Generator FIG. 14 is a circuit diagram illustrating an example of a circuit configuration of a voltage generator according to the second embodiment. FIG. 14 illustrates configurations of a regulator circuit 151A and a charge pump circuit 152. FIG. 14 also illustrates configurations of the sequencer 14 and the voltage monitor circuit 190.

As illustrated in FIG. 14, the sequencer 14 has a plurality of lookup tables TB including lookup tables TB1, TB2, . . . , and TBk (k is an integer greater than or equal to 2). The plurality of lookup tables TB correspond to, for example, 16 pieces of voltage value information from 2.4 V to 3.9 V in 0.1 V steps. In this case, k=16. The range and step width of the corresponding voltage values in the plurality of lookup tables TB are arbitrary. For example, the plurality of lookup tables TB may correspond to 32 pieces of voltage value information from 2.4 V to 3.9 V in 0.05 V steps. In this case, k=32. For example, the plurality of lookup tables TB may correspond to 11 pieces of voltage value information from 2.0 V to 4.0 V in 0.2 V steps. In this case, k=11.

In each of the lookup tables TB1 to TBk, information of control signals CS1 and CS2 is associated with each piece of voltage value information corresponding to the lookup table TB. The control signal CS1 is a signal for controlling the number of stages of charge pump units CP in the charge pump circuit 152. The control signal CS2 is a signal for changing a resistance value of a variable resistor R2A described later and for controlling an input voltage Vin1 to be input from the regulator circuit 151A to the charge pump circuit 152 and a clock generation circuit 153.

The voltage monitor circuit 190 monitors the magnitude of the voltage VCCH or the voltage VCC input to the pad PD2, and outputs voltage value information Vinfo of the voltage to the sequencer 14. Based on the voltage value information Vinfo input from the voltage monitor circuit 190, the sequencer 14 refers to the lookup table TB corresponding to the voltage value information closest to the voltage value information Vinfo. The sequencer 14 generates, for example, about 8 types (3 bits) to 32 types (5 bits) of various digital signals based on the lookup table TB referred to, and outputs the various digital signals as control signals CS1 and CS2 to the charge pump circuit 152 and the regulator circuit 151A, respectively.

The charge pump circuit 152 rearranges the charge pump units CP according to the control signal CS1 input from the sequencer 14. Specifically, the number of stages and the number of parallel couplings of the charge pump units CP are changed in accordance with the value of the input voltage Vin1 input from the regulator circuit 151A and a value of a desired output voltage Vout1. As a result, it is possible to boost the input voltage Vin1 with an optimal configuration of the charge pump units CP and output the desired output voltage Vout1.

The regulator circuit 151A includes the variable resistor R2A instead of the resistor R2. The variable resistor R2A divides the output voltage together with the resistor R1. The resistance value of the variable resistor R2A is changed by the control signal CS2 from the sequencer 14. By changing the resistance value of the variable resistor R2A, it is possible to change a feedback voltage to be input to an amplifier AMP from a couplings point where the resistor R1 and the variable resistor R2A are coupled. As a result, the magnitude of regulating a voltage can be changed in accordance with the magnitude of the voltage VCCH or the voltage VCC input to the regulator circuit 151A. More specifically, when the voltage VCCH is input to the pad PD2, the voltage is regulated to a voltage corresponding to the voltage VCCH, and the regulated voltage is output to the charge pump circuit 152 and the clock generation circuit 153 as the input voltage Vin1. When the voltage VCC is input to the pad PD2, the voltage is regulated to a voltage corresponding to the voltage VCC, and the regulated voltage is output to the charge pump circuit 152 and the clock generation circuit 153 as the input voltage Vin1. In this case, the regulator circuit 151A is configured such that a range in which the voltage is stepped down is as small as possible. Therefore, the input voltage Vin1 obtained by regulating the voltage VCCH is higher than the input voltage Vin1 obtained by regulating the voltage VCC. As a result, power efficiency in the entire voltage generator 15 can be improved.

### 2.2 Effect

The semiconductor memory device 10 according to the second embodiment can improve power efficiency. This effect will be described in detail below.

Depending on the configuration of the memory system 3, for example, a power supply voltage of about 2.7 V to 3.6 V corresponding to the voltage VCCH may be able to be supplied or may not be able to be supplied.

For example, in a case where the memory system 3 is an SSD coupled to a personal computer, the memory system 3 may have both a power supply that supplies a power supply voltage of, for example, about 2.35 V to 2.8 V corresponding to the voltage VCC, and a power supply that supplies a power supply voltage of, for example, about 2.7 V to 3.6 V corresponding to the voltage VCCH for uses not described in the present specification. In this case, the semiconductor memory device 10 according to the second embodiment can use the voltage VCCH, and thus can generate a voltage to be applied to a memory cell array 16 using an optimal configuration for the voltage VCCH, similarly to the first embodiment.

On the other hand, for example, in a case where the memory system 3 is a memory card coupled to a mobile terminal, the memory system 3 may not have a power supply that supplies a power supply voltage of, for example, about 2.7 V to 3.6 V corresponding to the voltage VCCH. In this case, the semiconductor memory device 10 according to the second embodiment can generate a voltage to be applied to the memory cell array 16 using a configuration optimal for another power supply voltage (specifically, the voltage VCC).

As described above, the semiconductor memory device 10 according to the second embodiment can generate a voltage to be applied to the memory cell array 16 using an optimal configuration not only in a memory system having a power supply corresponding to the voltage VCCH but also in a memory system not having a power supply corresponding to the voltage VCCH. Therefore, in either case, the power efficiency of the semiconductor memory device 10 can be improved.

In addition, the semiconductor memory device 10 according to the second embodiment includes the voltage monitor circuit 190. The voltage monitor circuit 190 monitors in particular, the voltage input to the pad PD2 and acquires the voltage value information Vinfo of the voltage input to the pad PD2. The sequencer 14 refers to the lookup table TB associated with each step width of a constant voltage value based on the voltage value information Vinfo input from the voltage monitor circuit 190, and outputs the control signals CS1 and CS2 to the charge pump circuit 152 and the regulator circuit 151A.

The regulator circuit 151A receives the control signal CS2 from the sequencer 14 and changes the resistance value of the variable resistor R2A in accordance with the magnitude of the voltage input to the pad PD2. That is, the step-down width of the voltage in the regulator circuit 151A can be changed for each magnitude of a voltage input to the pad PD2. As a result, for example, when a voltage (for example, 3.9 V) higher than an estimated value of the voltage VCCH is input to the pad PD2 of the regulator circuit 151A, the step-down width in the regulator circuit 151A can be reduced as compared with the first embodiment. That is, the regulator circuit 151A can output a higher input voltage Vin1 to the charge pump circuit 152 and the clock generation circuit 153.

Further, the charge pump circuit 152 receives the control signal CS1 from the sequencer 14, and is reconfigured to have an optimum configuration in accordance with the higher input voltage Vin1 output from the regulator circuit 151A. Therefore, there is a possibility that the number N of stages of the charge pump units CP in the charge pump circuit 152 can be reduced.

As indicated by Equation (1), since an output current Iout1 of the charge pump circuit 152 is determined in accordance with the number N of stages and the number M of parallel couplings of the charge pump units CP, the output current Iout1 can be increased by using the higher input voltage Vin1. In this case, for example, during the read operation, the non-selected word lines can be charged more quickly than in the first comparative example. As a result, the time required for the read operation can be shortened. Furthermore, as indicated by Equation (3), since the power efficiency Peff of the semiconductor memory device 10 is inversely proportional to N+1, the power efficiency Peff of the semiconductor memory device 10 can be further improved by reducing the number N of stages of the charge pump units CP in the charge pump circuit 152.

### 3. Third Embodiment

Next, a semiconductor memory device according to a third embodiment will be described below. In the following description, description of configurations equivalent to those in the second embodiment will be omitted, and configurations different from those in the second embodiment will be mainly described.

### 3.1 Configuration

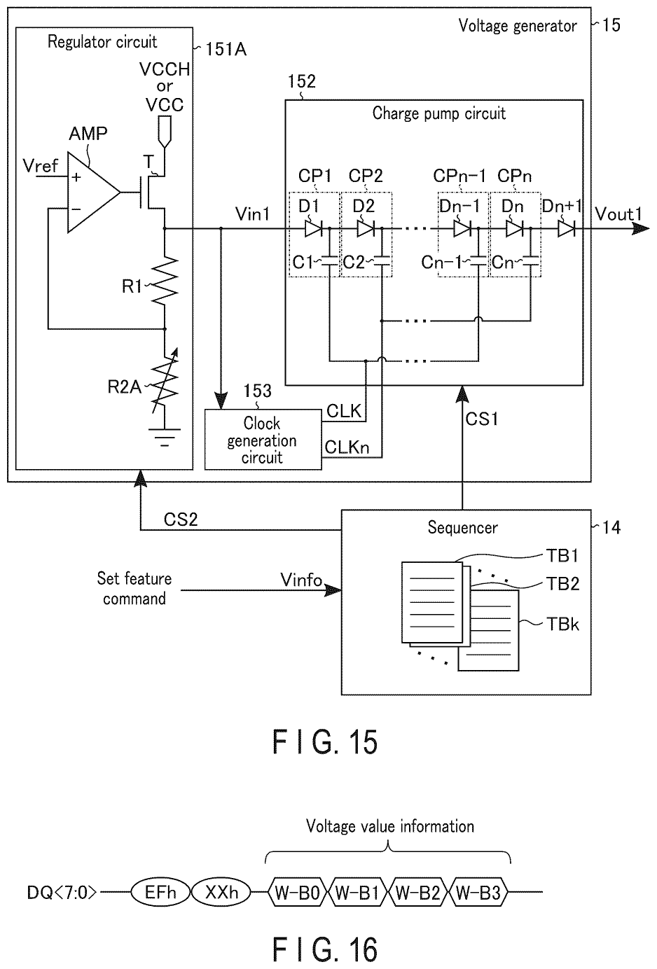

FIG. 15 is a circuit diagram illustrating an example of a circuit configuration of a voltage generator according to the third embodiment. FIG. 15 illustrates configurations of a regulator circuit 151A and a charge pump circuit 152. FIG. 15 also illustrates a configuration of a sequencer 14.

The semiconductor memory device 10 according to the third embodiment does not include the voltage monitor circuit 190. In the semiconductor memory device 10 according to the third embodiment, as illustrated in FIG. 15, voltage value information Vinfo of a voltage VCCH or a voltage VCC input to a pad PD2 is notified to the sequencer 14 by a set feature command.

### 3.2 Command Sequence

FIG. 16 is a command sequence diagram illustrating an example of setting of voltage value information in a memory system according to the third embodiment.

The memory controller 20 receives the voltage value information Vinfo of the voltage VCCH or VCC input to the pad PD2 of the semiconductor memory device 10 from a host 2. The memory controller 20 transmits the voltage value information Vinfo received from the host 2 to the semiconductor memory device 10 as a signal DQ<7:0>. The voltage value information Vinfo is input to the sequencer 14 via an input/output circuit 11.

First, the memory controller 20 transmits a command “EFh” and a command “XXh” to the semiconductor memory device 10. The command “EFh” is a set feature command, and is a command notifying a change in various processing modes. The command “XXh” is a feature address command and is a command for notifying a target to be changed in the various processing modes.

Thereafter, for example, the memory controller 20 converts the voltage value information Vinfo into 4-bit voltage value information “W-B0” to “W-B3”, and transmits the voltage value information “W-B0” to “W-B3” to the semiconductor memory device 10 over four cycles. The sequencer 14 restores the voltage value information Vinfo from the 4-bit voltage value information “W-B0” to “W-B3”, and uses the voltage value information Vinfo for determining which lookup tables TB to be referred to. The number of bits of the voltage value information is arbitrary.

Based on the restored voltage value information Vinfo, the sequencer 14 refers to the lookup table TB and outputs control signals CS1 and CS2 to the charge pump circuit 152 and the regulator circuit 151A, respectively.

As described above, the sequencer 14 receives the set feature command from the outside of the semiconductor memory device 10, and changes the magnitude of the input voltage Vin1 and the number of stages of the charge pump units in the charge pump circuit 152 based on the voltage value information Vinfo set by the set feature command.

### 3.3 Effect

Similarly to the second embodiment, the semiconductor memory device 10 according to the third embodiment can shorten the time required for a read operation and improve the power efficiency.

In the semiconductor memory device 10 according to the third embodiment, the magnitude of the input voltage Vin1 in the charge pump circuit 152 and the number of stages of the charge pump units are changed by the command issued by the memory controller 20. Therefore, when the voltage value fluctuates due to disturbance, the control by the command can be performed. Therefore, the robustness of the voltage generator 15 is improved, and the reliability of the semiconductor memory device 10 is improved.

### 4. Fourth Embodiment

Next, a semiconductor memory device according to a fourth embodiment will be described. In the following description, description of configurations equivalent to those in the first embodiment will be omitted, and configurations different from those in the first embodiment will be mainly described.

### 4.1 Configuration

The semiconductor memory device 10 according to the fourth embodiment is, for example, a DRAM capable of storing data in a volatile manner. A memory cell array 16 according to the fourth embodiment includes a plurality of memory cells, a plurality of word lines, and a plurality of bit lines. Each of the memory cells can store 1-bit data. Each of the memory cells is provided in association with one word line and one bit line.

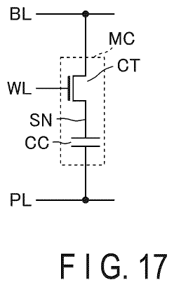

FIG. 17 is a circuit diagram illustrating components of a memory cell included in a memory cell array and coupling of the components in the semiconductor memory device according to the fourth embodiment. As illustrated in FIG. 17, each of the memory cells MC includes a cell transistor CT and a cell capacitor CC. The cell transistor CT is, for example, an n-type MOSFET. The cell capacitor CC is coupled to a plate line PL at a first end of the cell capacitor CC, and is coupled to a first end of the cell transistor CT at a second end of the cell capacitor CC. The cell capacitor CC stores data using charges accumulated at a node coupled to the cell transistor CT. The node coupled between the cell capacitor CC and the cell transistor CT is referred to as a storage node SN. A state in which the storage node SN accumulates charges or does not accumulate charges is associated with a state in which the memory cell MC stores “1” data or a state in which the memory cell MC stores “0” data. Hereinafter, as an example, a state in which the storage node SN is charged to a relatively positive potential is treated as a state in which the memory cell MC stores “1” data, and a state in which the storage node SN is not charged to a relatively positive potential is treated as a state in which the memory cell MC stores “0” data.

The cell transistor CT is coupled to one bit line BL at a second end of the cell transistor CT, and is coupled to one word line WL at a gate terminal of the cell transistor CT.

In addition, in a power supply pad group 19 according to the fourth embodiment, for example, a voltage VCC having a voltage value of about 1.0 V to 1.4 V is input to a pad PD1. As a more specific example, the voltage VCC has a voltage value of about 1.2 V. A power supply domain DM1 is coupled to the pad PD1. The power supply domain DM1 is used, for example, not only for driving peripheral circuits but also for generating a voltage to be applied to the bit lines BL. A voltage VCCH that is higher than the voltage VCC and has a voltage value of, for example, about 1.5 V to 2.0 V is input to a pad PD2. As a more specific example, the voltage VCCH has a voltage value of about 1.8 V. A power supply domain DM2 is coupled to the pad PD2. The power supply domain DM2 is used, for example, to generate a voltage to be applied to the word lines WL.

### 4.2 Operation

When “1” data is to be written to the memory cell MC, the voltage VCC is applied from the power supply domain DM1 to the bit line BL corresponding to the memory cell MC, and the voltage VCCH is applied from the power supply domain DM2 to the word line WL corresponding to the memory cell MC. A voltage VSS is applied to the plate line PL. In this case, the cell transistor CT is turned on, the first end of the cell capacitor CC is coupled to the plate line PL, and the second end of the cell capacitor CC is coupled to the bit line BL. Since the cell capacitor CC is charged due to the difference in electrical potential between the bit line BL and the plate line PL, the storage node SN is charged to a relatively positive potential.

When “0” data is to be written to the memory cell MC, the voltage VSS is applied to the bit line BL corresponding to the memory cell MC, and the voltage VCCH is applied from the power supply domain DM2 to the word line WL corresponding to the memory cell MC. The voltage VSS is applied to the plate line PL. In this case, the cell transistor CT is turned on, the first end of the cell capacitor CC is coupled to the plate line PL, and the second end of the cell capacitor CC is coupled to the bit line BL. Since the difference in electrical potential between the bit line BL and the plate line PL becomes zero and the cell capacitor CC is discharged, the storage node SN is not charged to a relatively positive potential.

### 4.3 Effect

When “1” data is to be written to the memory cell MC, the voltage VCC is applied to the second end of the cell transistor CT via the bit line BL. In this case, in order to turn on the cell transistor CT, it is necessary to apply a voltage higher than the voltage VCC to the gate terminal.

The semiconductor memory device 10 according to the fourth embodiment has the power supply domain DM2 to which the voltage VCCH higher than the voltage VCC is input. Therefore, by applying the voltage VCCH from the power supply domain DM2 to the word line WL, the cell transistor CT can be turned on when “1” data is to be written to the memory cell MC. Therefore, it is not necessary to generate a voltage to be separately applied to the word line WL by boosting the voltage VCC or the like, and there is no current and voltage that are lost at the time of boosting, so that the power efficiency of the semiconductor memory device 10 can be improved.

### 4.4 Modifications

The semiconductor memory device 10 according to the fourth embodiment described above can be variously modified.

For example, in the fourth embodiment, the voltage VCCH is used for generating a voltage to be applied to the word line WL, but may be used for other purposes. For example, the power supply domain DM2 may include some of the peripheral circuits, and the voltage VCCH may be input as a drive voltage of the row decoder 17, the sense amplifier module 18, and the like. By replacing either one or both of the power supply voltages of the row decoder 17 and the sense amplifier module 18 with the voltage VCCH, the drive voltages of various circuits are increased, and it is possible to reduce malfunctions due to voltage drop, so that the reliability of the memory cell array 16 can be improved.

### 5. Others

In the above-described embodiments, the NAND flash memory and the DRAM have been described as examples of the semiconductor memory device, but the present invention is also applicable to other semiconductor memory devices. For example, the invention according to the first to third embodiments can also be applied to a NOR flash memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell;
a first power supply domain coupled to a first power supply pad to which a first voltage is input, the first power supply domain including a sequencer; and
a second power supply domain coupled to a second power supply pad to which a second voltage is input, the second power supply domain including a charge pump circuit that generates a voltage to be applied to the memory cell,
wherein
the charge pump circuit includes
a first diode having an input terminal coupled to an input terminal of the charge pump circuit,
a first capacitor having a first end coupled to an output terminal of the first diode and a second end coupled to the second power supply pad,
a second diode having an output terminal coupled to an output terminal of the charge pump circuit, and
a second capacitor having a first end coupled to an output terminal of the second diode and a second end coupled to the second power supply pad.

2. The semiconductor memory device according to claim 1, wherein
the second power supply domain further includes a clock generation circuit that generates a first clock signal and a second clock signal obtained by inverting the first clock signal,
the first clock signal is input to the second end of the first capacitor, and
the second clock signal is input to the second end of the second capacitor.

3. The semiconductor memory device according to claim 1, wherein
the charge pump circuit is reconfigured into either
a first mode in which the output terminal of the first diode is coupled to an input terminal of the second diode, and the first diode and the second diode are coupled in series, or
a second mode in which the input terminal of the second diode is coupled to the second power supply pad, the output terminal of the first diode is coupled to the output terminal of the second diode, and the first diode and the second diode are coupled in parallel, and
the sequencer changes a voltage to be output from the charge pump circuit by switching a configuration of the charge pump circuit to the first mode or the second mode.

4. The semiconductor memory device according to claim 1, wherein
the second voltage has a voltage value higher than the first voltage.

5. The semiconductor memory device according to claim 4, wherein
the first voltage has a voltage value of 2.35 V to 2.8 V, and
the second voltage has a voltage value of 2.7 V to 3.6 V.

6. The semiconductor memory device according to claim 3, wherein
the sequencer switches the configuration of the charge pump circuit to the first mode or the second mode in accordance with voltage value information of the second voltage.

7. The semiconductor memory device according to claim 6, further comprising
a voltage monitor circuit coupled to the second power supply pad, wherein
the voltage monitor circuit monitors a magnitude of the second voltage and outputs the voltage value information of the second voltage to the sequencer.

8. The semiconductor memory device according to claim 6, further comprising
the voltage value information of the second voltage is input to the sequencer from an external controller.

9. The semiconductor memory device according to claim 6, wherein
the second power supply domain further includes a first regulator circuit, and
the first regulator circuit regulates the second voltage and outputs the regulated second voltage to the charge pump circuit.

10. The semiconductor memory device according to claim 9, wherein
the sequencer changes, in accordance with the voltage value information of the second voltage, the voltage to be output from the first regulator circuit to the charge pump circuit.

11. The semiconductor memory device according to claim 10, further comprising
a voltage monitor circuit coupled to the second power supply pad, wherein
the voltage monitor circuit monitors a magnitude of the second voltage and outputs the voltage value information of the second voltage to the sequencer.

12. The semiconductor memory device according to claim 10, wherein
the voltage value information of the second voltage is input to the sequencer from an external controller.

13. The semiconductor memory device according to claim 1, wherein
the first power supply domain further includes a second regulator circuit, and
the second regulator circuit regulates the first voltage and outputs the regulated first voltage to the sequencer.

14. The semiconductor memory device according to claim 6, wherein
the first voltage and the second voltage have a same voltage value.

15. The semiconductor memory device according to claim 1, wherein
the charge pump circuit includes
a plurality of charge pump units each including a diode and a capacitor having a first end coupled to an output terminal of the diode and a second end coupled to the second power supply pad,
the charge pump circuit is capable of arbitrarily changing a number of stages of the charge pump units, and
the sequencer determines the number of stages of the charge pump units in the charge pump circuit, and changes a voltage to be output from the charge pump circuit by changing a configuration of the charge pump circuit.

16. The semiconductor memory device according to claim 15, wherein
the sequencer changes the number of stages of the charge pump units in the charge pump circuit in accordance with voltage value information of the second voltage.

17. The semiconductor memory device according to claim 16, wherein
when the second voltage has a first voltage value, the sequencer changes the number of stages of the charge pump units in the charge pump circuit to M, and
when the second voltage is a second voltage value higher than the first voltage value, the sequencer changes the number of stages of the charge pump units in the charge pump circuit to N less than M.

18. A semiconductor memory device comprising:
a memory cell including a cell transistor having a first end coupled to a cell capacitor;
a first power supply domain that is coupled to a first power supply pad to which a first voltage is input, and that generates a voltage to be applied to a bit line; and
a second power supply domain that is coupled to a second power supply pad to which a second voltage is input, and that generates a voltage to be applied to a word line,
wherein
the cell transistor has a second end coupled to the bit line, and
the cell transistor has a gate terminal coupled to the word line.

19. The semiconductor memory device according to claim 18, wherein
the second voltage has a voltage value higher than the first voltage.

20. The semiconductor memory device according to claim 19, wherein
the first voltage has a voltage value of 1.0 V to 1.4 V, and
the second voltage has a voltage value of 1.5 V to 2.0 V.
